(19) United States
(12) Patent Application Publication
(10) Pub. No.: US 2014/0154127 A1
(43) Pub. Date: Jun. 5, 2014

(54) Alloy and Sputtering Target Material for Soft-Magnetic Film Layer in Perpendicular Magnetic Recording Medium, and Method for Producing the Same

(71) Applicant: Sanyo Special Steel Co., Ltd., Himeji-Shi (JP)

(72) Inventors: Toshiyuki Sawada, Himeji-Shi (JP); Akihiko Yanagitani, Himeji-Shi (JP)

(73) Assignee: Sanyo Special Steel Co., Ltd., Himeji-Shi (JP)

(21) Appl. No.: 14/175,409

(22) Filed: Feb. 7, 2014

Related U.S. Application Data
(62) Division of application No. 12/212,329, filed on Sep. 17, 2008.

(30) Foreign Application Priority Data
Sep. 18, 2007 (JP) 2007-241101

(51) Int. Cl. C23C 14/34

(52) U.S. Cl. CPC C23C 14/3414
USPC 419/32

(57) ABSTRACT

There are provided a sputtering target material for a soft-magnetic film layer with a high saturation magnetic flux density and high amorphous properties and a method for producing the sputtering target material. The target material is made of an alloy comprising one or more of Zr, Hf, Nb, Ta and B in an amount satisfying 5 at %≦(Zr+Hf+Nb+Ta)+B/2≦10 at % and having 7 at % or less of B; 0 to 5 at % in total of Al and Cr; and the balance being Co and Fe in an amount satisfying 0.20≦Fe/(Fe+Co)≦0.65 (at % ratio) with unavoidable impurities.

### CROSS-REFERENCE TO RELATED APPLICATION

The present application is a divisional application of U.S. patent application Ser. No. 12/212,329 filed on Sep. 17, 2008 which claims priority to Japanese Patent Application No. 2007-241101 filed on Sep. 18, 2007, the entire disclosures of which are incorporated herein by reference.

### BACKGROUND OF THE INVENTION

1. Field of the Invention

The present invention relates to an alloy (Co, Fe) (Zr, Hf, Nb, Ta, B) and a sputtering target material used for a soft-magnetic film layer in a perpendicular magnetic recording medium. The present invention also relates to a method for producing the alloy and the sputtering target material.

2. Description of Related Art

In recent years, there have been remarkable progresses in magnetic recording technology, and heightening record densities in magnetic record media is proceeding due to increasing drive capacities. In magnetic record media for longitudinal magnetic recording systems currently used worldwide, however, attempts to realize high record densities result in refined record bits, which require high coercivity to such an extent that recording cannot be conducted with the record bits. In view of this, a perpendicular magnetic recording system is being studied as a means for solving these problems and improving record density.

The perpendicular magnetic recording system is a system in which a magnetization-easy axis is oriented in the direction perpendicular to a medium surface in the magnetic film of a perpendicular magnetic record medium, and is suitable for high record densities. For the perpendicular magnetic recording system, a two-layered record medium has been developed having a magnetic record film layer with an improved record sensitivity and a soft magnetic film layer. A CoCrPt—SiO₂ based alloy is generally used in the magnetic record film layer.

On the other hand, a CoZrNb/Ta alloy or the like has been proposed for a soft-magnetic film layer, as disclosed in Japanese Patent Laid-Open Publication No. 2005-320627 proposes use of. A high saturation magnetic flux density and high amorphous properties are required for the soft-magnetic film layer in the perpendicular magnetic recording medium. The CoZrNb/Ta alloy disclosed in Japanese Patent Laid-Open Publication No. 2005-320627 may, however, result in a lower saturation magnetic flux density, compared with the saturation magnetic flux density required for the soft-magnetic film layer of the perpendicular magnetic recording medium.

In addition, when an alloy with a high saturation magnetic flux density is used for the soft-magnetic film layer, a target material for forming this film also results in a high saturation magnetic flux density, causing a decrease in PTF value, which influences sputtering rate during magnetron sputtering. In the meantime, PTF value is the proportion (%) of a direct current magnetic field having passed through a ferromagnetic sputtering target as defined in ASTM F1761-00, the entire disclosure of which is incorporated herein by reference. Amorphous properties mean a degree of easiness with which an alloy becomes amorphous during quenched solidification or sputtering.

### SUMMARY OF THE INVENTION

The inventors have now found that an alloy comprising one or more of Zr, Hf, Nb, Ta and B in an amount satisfying 5 at %≦(Zr+Hf+Nb+Ta)+B/2≦10 at % and having 7 at % or less of B; 0 to 5 at % in total of Al and Cr; and the balance being Co and Fe in an amount satisfying 0.20≦Fe/(Fe+Co)≦0.65 (at % ratio) with unavoidable impurities is excellent as a sputtering target material for a soft-magnetic film layer in a perpendicular magnetic recording medium with a high saturation magnetic flux density and high amorphous properties.

The inventors have also found that a sputtering target material with a high PTF value and a high relative density can be obtained by, in the production of the target material, mixing a first powder satisfying 1.00≧Fe/(Fe+Co)≧0.90 (at % ratio) and 3 at %≦(Zr+Hf+Nb+Ta)+B/2≦12 at % with a second powder satisfying 0.00≦Fe/(Fe+Co)≦0.10 (at % ratio) and 3 at %≦(Zr+Hf+Nb+Ta)+B/2≦12 at %; and consolidating the mixed powder at 800 to 1250° C. and at 100 to 1000 MPa.

According an aspect of the present invention, there is provided a sputtering target material for a soft-magnetic film layer in a perpendicular magnetic recording medium, the target being made of an alloy comprising:

one or more of Zr, Hf, Nb, Ta and B in an amount satisfying 5 at %≦(Zr+Hf+Nb+Ta)+B/2≦10 at % and having 7 at % or less of B;

Al and Cr: 0 to 5 at % in total; and

the balance being Co and Fe in an amount satisfying 0.20≦Fe/(Fe+Co)≦0.65 (at % ratio) with unavoidable impurities.

According to another aspect of the present invention, a method for producing the sputtering target material is provided comprising the steps of:

a) mixing a first powder and a second powder to form a mixed powder, wherein the first powder comprises:

one or more of Zr, Hf, Nb, Ta and B in an amount satisfying 3 at %≦(Zr+Hf+Nb+Ta)+B/2≦12 at %;

Al and Cr: 0 to 5 at % in total; and

the balance being Co and Fe in an amount of satisfying 1.00≧Fe/(Fe+Co)≧0.90 (at % ratio) with unavoidable impurities, and wherein the second powder comprises:

one or more of Zr, Hf, Nb, Ta and B having an amount of satisfying 3 at %≦(Zr+Hf+Nb+Ta)+B/2≦12 at %;

Al and Cr: 0 to 5 at % in total; and

the balance being Co and Fe in an amount satisfying 0.00≦Fe/(Fe+Co)≦0.10 (at % ratio) with unavoidable impurities; and

b) consolidating the mixed powder at 800 to 1250° C. and at 100 to 1000 MPa to form the sputtering target material.

### DETAILED DESCRIPTION OF THE INVENTION

The present invention will be described in detail below.

### Alloy and Target Material for Soft-Magnetic Film Layer

The sputtering target material according to the present invention is a sputtering target material for a soft-magnetic film layer in a perpendicular magnetic recording medium and is made of a Co—Fe based alloy. The Co—Fe based alloy comprises one or more of Zr, Hf, Nb, Ta and B in an amount satisfying 5 at %≦(Zr+Hf+Nb+Ta)+B/2≦10 at % and having 7 at % or less of B; 0 to 5 at % in total of Al and Cr; and the balance being Co and Fe in an amount satisfying 0.20≦Fe/(Fe+Co)≦0.65 (at % ratio) with unavoidable impurities.

The reasons for the compositional limitations in the alloy and the sputtering target material for the soft-magnetic film layer are as follows.

Fe/(Fe+Co) being at % ratio is a parameter having a great influence on saturation magnetic flux density, amorphous properties and atmospheric corrosion resistance. When Fe/(Fe+Co) is within a range of 0.20 to 0.65, the saturation magnetic flux density improves as the proportion of Fe becomes larger. When Fe/(Fe+Co) exceeds 0.65, however, the saturation magnetic flux density is no longer improved, causing a significant degradation in corrosion resistance. Fe/(Fe+Co) of less than 0.20 results in insufficient saturation magnetic flux density. For these reasons, Fe/(Fe+Co) should be within a range of from 0.20 to 0.65, preferably from 0.25 to 0.50, in the alloy and the sputtering target material.

Each of Zr, Hf, Nb, Ta and B has a eutectic state diagram to Fe and Co and is an element capable of forming an amorphous phase. The concentration of each of these elements, except for B, is around a level of 8 to 13 at % and only the concentration of B is slightly less than 20 at %. It is therefore possible to use a total amount of Zr, Hf, Nb, Ta and B/2. The total amount of (Zr+Hf+Nb+Ta)+B/2 of less than 5 at % does not provide sufficient eutectic properties. When the amount of (Zr+Hf+Nb+Ta)+B/2 exceeds 10 at %, the eutectic properties are saturated to degrade the saturation magnetic flux density. When the content of B exceeds 7 at %, the corrosion resistance is degraded. For these reasons, the total amount of (Zr+Hf+Nb+Ta)+B/2 should be within a range of from 5 to 10 at % in the alloy and the sputtering target material, while the content of B should be within a range of 7 at % or less, preferably 1 to 7 at %.

### Producing Method

A preferred method for producing the alloy or a sputtering target material according to the present invention is explained below. The method for producing the alloy or the sputtering target material according to the present invention is not limited to the following method.

In a producing method according to a preferred aspect of the present invention, a first powder and a second powder is mixed to form a mixed powder. The first powder comprises one or more of Zr, Hf, Nb, Ta and B in an amount satisfying 3 at %≦(Zr+Hf+Nb+Ta)+B/2≦12 at %; 0 to 5 at % in total of Al and Cr; and the balance being Co and Fe in an amount of satisfying 1.00≧Fe/(Fe+Co)≧0.90 (at % ratio) with unavoidable impurities. The second powder comprises one or more of Zr, Hf, Nb, Ta and

B having an amount of satisfying 3 at %≦(Zr+Hf+Nb+Ta)+B/2≦12 at %; 0 to 5 at % in total of Al and Cr; and the balance being Co and Fe in an amount satisfying 0.00≦Fe/(Fe+Co)≦0.10 (at % ratio) with unavoidable impurities.

In this way, the target material is formed not by consolidating a powder consisting of a single composition but by consolidating a mixed powder comprising two kinds of powders each having a relatively low saturation magnetic flux density in a given proportion. By this method, it is possible to obtain a target material having a relatively low saturation magnetic flux density, in spite of a high saturation magnetic flux density exhibited by an alloy with a uniform composition. It is therefore possible to avoid a situation where a high saturation magnetic flux density causes a decrease in PTF value to reduce a deposition rate during formation of a film in a magnetron sputtering using a target material made of an excellent alloy having a high saturation magnetic flux density and high eutectic properties.

In dividing the total composition of the target material into two kinds of raw-material powders each having a different composition, the saturation magnetic flux density of each of the powders can be reduced by setting Fe/(Fe+Co) of one of the raw-material powders to 1.00 to 0.90 as well as by setting Fe/(Fe+Co) of the other of the raw-material powders to 0.00 to 0.10. Due to a difference in sputtering rate between the group of Zr, Hf, Nb, Ta and B and the group of Fe and Co, a large difference in added amount between these groups of the powders leads to a problem that concave and convex portions are generated on the surface of the target material to cause defects such as particles as the sputtering is continued. Particularly, in a case where the amount of (Zr+Hf+Nb+Ta)+B/2 in one of the powders is less than 3 at % or it exceeds 12 at %, the number of the particles increases.

Further, when an alloy target material satisfying Fe/(Fe+Co) of 0.20 to 0.65 is consolidated as a raw-material of a single powder, cracks or chips may be produced at machining after the consolidation. The reason for this is not clear in detail, but is thought that a brittle ordered phase (α′ phase) as observed in the vicinity of Fe/(Fe+Co)=0.5 in the Co—Fe binary phase diagram is also formed in the parent phase of the alloy according to the present invention. From this respect, it is effective to separate the raw-material powder into two kinds of powders satisfying Fe/(Fe+Co) of 1.00 to 0.90 and Fe/(Fe+Co) of 0.00 to 0.10, respectively.

The inventors have also found that, in producing an alloy target material, consolidating two kinds of raw-material powders each satisfying Fe/(Fe+Co) of 1.00 to 0.90 and Fe/(Fe+Co) of 0.00 to 0.10 leads to a higher relative density, compared with a case of consolidating a single raw-material powder under the same condition. The reason for this is not clear in detail, but is assumed as follows. In a case of using the raw-material powder obtained by mixing two kinds of powders, as compared to a case of using a single powder as the raw-material, it is considered that a Fe-rich region corresponding to the powder satisfying Fe/(Fe+Co) of 1.00 to 0.90 and a Co-rich region corresponding to the powder satisfying Fe/(Fe+Co) of 0.00 to 0.10 are formed at a contact point between the two kinds of powders, causing a high concentration gradient at the contact point. It is therefore considered that, since a mutual diffusion of Co atom and Fe atom occurs significantly for reducing the concentration gradient, sintering is further advanced to increase the relative density.

According to a preferred aspect of the present invention, the mixed powder thus obtained is consolidated at 800 to 1250° C. and at 100 to 1000 MPa to form an alloy or a sputtering target material. Consolidation at a temperature below 800° C. or at a pressure of less than 100 MPa results in a low relative density. Also, consolidation at a temperature above 1250° C. causes a partial melting to generate solidification pores. Further, consolidation at a pressure of more than 1000 MPa is industrially difficult. Accordingly, the consolidation temperature is set to 800 to 1250° C., preferably 850 to 1100° C., while the consolidation pressure is set to 100 to 1000 MPa, preferably 120 to 600 MPa.

According to a preferred aspect of the present invention, only the first powder or both of the first powder and the second powder may comprise 5 at % or less of Al+Cr, and the alloy may comprise 5 at % or less of Al+Cr as a whole. According to this preferred producing method, since the Fe-rich raw-material (low corrosion resistance) and the Co-rich raw-material (high corrosion resistance) are mixed together for consolidation, a kind of local cell is established between the both powders, resulting in forming a material relatively easy to rust for target material. Therefore, addition Al and Cr into at least the Fe-rich raw-material powder or into both of the powders can make the target material difficult to rust. However, when the amount of Al+Cr exceeds 5 at %, the effect is no longer improved. Also, a total amount of Al+Cr in the target material of more than 5 at % causes a decrease in saturation magnetic flux density for a thin film formed by sputtering the target. Therefore, the amount of Al+Cr is set to 5 at % or less, preferably 1 to 5 at %.

Normally, a soft-magnetic film layer in a perpendicular magnetic recording medium can be produced by sputtering a sputtering material having the same composition as that of a soft-magnetic film layer to form a thin film on a glass substrate. The thin film coated by sputtering is quenched. On the other hand, in the present invention, a quenched thin strip produced through a single-roll-type liquid quenching device is used as a specimen in examples and comparative examples described below. This is to evaluate influences on various characteristics by constituents of a thin film actually quenched and formed by sputtering, with the liquid quenched thin strip instead.

### EXAMPLES

The present invention is explained in detail below with reference to examples.

### Example A

A raw-material of 30 g weighed by constituents in Table 1 was arc-melted under reduced pressure of Ar in a water-cooled copper hearth having a diameter of 10×40 mm to prepare a molten base material for a quenched thin strip. Production of the quenched thin strip was conducted in a single roll system. Specifically, this molten base material was set in a silica tube having a diameter of 15 mm and was tapped at an atmosphere pressure of 61 kPa, at an atomizing pressure difference of 69 kPa and at a rotational number of 3000 rpm of a copper roll (diameter of 300 mm). The diameter of the tap nozzle was set to 1 mm, while the gap between the copper roll and the tap nozzle was set to 0.3 mm. The tap temperature was set to a temperature right after the melting of each molten base material. The quenched thin strip produced in this way was used as a sample material and the following evaluations were conducted.

### Evaluation 1: Saturation Magnetic Flux Density

Saturation magnetic flux density of the quenched thin strip was measured at an applied magnetic field of 1200 kA/m by a VSM device (vibration-sample-type magnetometer). The sample material weighed approximately 15 mg.

### Evaluation 2: Amorphous Properties

The evaluation of the amorphous properties in the quenched thin strip was conducted as follows. When an X-ray diffraction pattern of the amorphous material is measured, no diffraction peak is observed to show a halo pattern specific to amorphous materials. Although a diffraction peak is observed in a material not completely amorphous, the height of the peak is lower than that of a crystal material to show a broad peak having a large half-bandwidth (a width at a half height of the diffraction peak). This half-bandwidth has a correlation with amorphous properties of the material. As the amorphous properties are higher, the diffraction peak becomes broader with increasing half-bandwidth. Therefore, the amorphous properties were evaluated by the following method.

A sample material was attached on a glass plate with a double-faced tape to obtain a diffraction pattern by an X-ray diffraction device. At this time, the sample material was attached on the glass plate so that a surface to be measured could be a copper-roll-contact surface of the quenched thin strip. The X-ray source was Cu-kα ray, and the measurement was conducted at a scan speed of 4°/min. The width at a half height of the main peak in the diffraction pattern was image-analyzed to determine the half-bandwidth for evaluating amorphous properties.

TABLE 1

| | | | | | | | | | | (Zr + Hf + | | Saturation | Half- |
|---|---|---|---|---|---|---|---|---|---|---|---|---|---|
| | | | | | | | | | | Nb + Ta) + | Fe/ | Magnetic | Band- |
| | Constituent of Quenched Thin Strip (at %) | | | | | | | | | B/2 | (Fe + | Flux | width |
| No | Fe | Zr | Hf | Nb | Ta | B | Al | Cr | Co | (at %) | Co) | Density (T) | (°) |

Examples of Present Invention

| | | | | | | | | | | | | | |
|---|---|---|---|---|---|---|---|---|---|---|---|---|---|
| 1 | 18.4 | 8 | 0 | 0 | 0 | 0 | 0 | 0 | Balance | 8 | 0.20 | 1.42 | 0.9 |
| 2 | 26.6 | 4.5 | 0 | 0 | 0 | 7 | 0 | 0 | Balance | 8 | 0.30 | 1.55 | 0.6 |
| 3 | 36.8 | 0 | 4 | 2 | 2 | 0 | 0 | 0 | Balance | 8 | 0.40 | 1.60 | 0.6 |
| 4 | 46.0 | 4 | 0 | 4 | 0 | 0 | 0 | 0 | Balance | 8 | 0.50 | 1.74 | 0.6 |
| 5 | 55.2 | 4 | 0 | 0 | 4 | 0 | 0 | 0 | Balance | 8 | 0.60 | 1.79 | 0.6 |
| 6 | 57.5 | 0 | 4.5 | 0 | 0 | 7 | 0 | 0 | Balance | 8 | 0.65 | 1.82 | 0.6 |
| 7 | 38.0 | 5 | 0 | 0 | 0 | 0 | 0 | 0 | Balance | 5 | 0.40 | 1.82 | 0.4 |
| 8 | 37.2 | 7 | 0 | 0 | 0 | 0 | 0 | 0 | Balance | 7 | 0.40 | 1.67 | 0.6 |
| 9 | 35.0 | 5.5 | 0 | 0 | 0 | 7 | 0 | 0 | Balance | 9 | 0.40 | 1.66 | 1.0 |
| 10 | 36.0 | 6 | 0 | 2 | 2 | 0 | 0 | 0 | Balance | 10 | 0.40 | 1.37 | 2.2 |
| 11 | 36.8 | 8 | 0 | 0 | 0 | 0 | 0 | 1 | Balance | 8 | 0.40 | 1.53 | 1.0 |
| 12 | 36.8 | 4 | 4 | 0 | 0 | 0 | 3 | 0 | Balance | 8 | 0.40 | 1.40 | 1.1 |
| 13 | 36.8 | 4 | 4 | 0 | 0 | 0 | 3 | 2 | Balance | 8 | 0.40 | 1.34 | 0.9 |

Comparative Example

| | | | | | | | | | | | | | |
|---|---|---|---|---|---|---|---|---|---|---|---|---|---|
| 14 | 13.8 | 8 | 0 | 0 | 0 | 0 | 0 | 0 | Balance | 8 | 0.15 | 1.29 | 0.9 |
| 15 | 62.0 | 0 | 4.5 | 0 | 0 | 7 | 0 | 0 | Balance | 8 | 0.70 | 1.76 | 0.6 |
| 16 | 38.4 | 4 | 0 | 0 | 0 | 0 | 0 | 0 | Balance | 4 | 0.40 | 1.87 | 0.1 |
| 17 | 35.6 | 7 | 0 | 2 | 2 | 0 | 0 | 0 | Balance | 11 | 0.40 | 1.28 | 2.5 |
| 18 | 34.4 | 4 | 4 | 0 | 0 | 0 | 3 | 3 | Balance | 8 | 0.40 | 1.21 | 0.8 |
| 19 | 57.2 | 0 | 4 | 0 | 0 | 8 | 0 | 0 | Balance | 8 | 0.65 | 1.79 | 0.7 |

Note) Underlined part is outside the conditions of the present invention.

### Evaluation 3: Corrosion Resistance

In regard to Example No. 6 having a Fe/(Fe+Co) ratio of 0.65 and Comparative Example No. 15 having a Fe/(Fe+Co) ratio of 0.70, a salt spray test (5% NaCl-35° C.-16 h) was conducted using a sample in which a quenched thin strip was attached on a glass plate with a double-faced tape. As a result, the quenched thin strip having 0.65 of a Fe/(Fe+Co) ratio (Example No. 6) partly had rust, but the quenched thin strip having 0.70 of the Fe/(Fe+Co) ratio (Comparative Example No. 15) had rust over its entire surface. The quenched thin strip exceeding 0.65 of the Fe/(Fe+Co) ratio did not provide an effect of increasing the saturation magnetic flux density and had degradation of corrosion resistance. When a quenched thin strip of Comparative Example No. 19 having 0.65 of the Fe/(Fe+Co) ratio and 8 at % of B was produced to conduct the salt spray test as mentioned above, rust was observed over an entire surface of the quenched thin strip.

### Results

The results in cases of quenched thin strips are shown in

Table 1. No. 1 to 13 are examples of the present invention while No. 14 to 19 are comparative examples. In regard to Comparative Example No. 14, since the value of Fe/(Fe+Co) is as low as 0.15, the saturation magnetic flux density is low. In regard to Comparative Example No. 15, since the value of Fe/(Fe+Co) is as high as 0.70, the corrosion resistance is degraded as described above. In regard to Comparative Example No. 16, since the value of (Zr+Hf+Nb+Ta)+B/2 is as low as 4, the half-bandwidth is small. In regard to Comparative Example No. 17, since the value of (Zr+Hf+Nb+Ta)+B/2 is high, the saturation magnetic flux density is low. In regard to Comparative Example No. 18, since the added amount of Al+Cr is high, the saturation magnetic flux density is low. In regard to Comparative Example No. 19, since the amount of B is high, the corrosion resistance is degraded as described above. In this way, the alloy of the present invention is advantageous in saturation magnetic flux density, amorphous properties and corrosion resistance in a state of being quenched.

### Example B

In Example B, an alloy powder using as a raw-material was produced by a gas atomizing method to measure the saturation magnetic flux density for studying a raw-material powder composition low in saturation magnetic flux density. The PTF value of a target material produced by consolidating and machining each of the raw-material powders was measured to study influences of the raw-material powder composition on PFT value. At the same time, the consolidation condition, the relative density of the target material, and corrosion resistance of the target material were measured.

Specifically, the alloy powder having the composition shown in table 2 was produced by a gas atomizing method using an Ar gas, a nozzle diameter of 6 mm and a gas pressure of 5 MPa. The produced powder was then classified into 500 μm or less to obtain Powder No. 1 to 10. The following evaluations were conducted on the powder thus obtained.

### Evaluation 1: Saturation Magnetic Flux Density of Raw-Material Powder

The saturation magnetic flux density of the raw-material powder was measured at an applied magnetic field of 1200 kA/m by a VSM device (vibration sample type magnetic magnetometer). The sample had a weight of approximately 200 mg. The results are shown in Table 2.

TABLE 2

| | | | | | | | | | | (Zr + | | Saturation |
|---|---|---|---|---|---|---|---|---|---|---|---|---|
| | | | | | | | | | | Hf + Nb + | | Magnetic |
| | Constituent of Gas Atomized Powder (at %) | | | | | | | | | Ta) + B/2 | Fe/ | Flux |
| No. | Zr | Hf | Nb | Ta | B | Al | Cr | Co | Fe | (at %) | (Fe +Co) | Density (T) |

Examples of Present Invention

| | | | | | | | | | | | | |
|---|---|---|---|---|---|---|---|---|---|---|---|---|
| 1 | 6 | 0 | 2 | 2 | 0 | 0 | 0 | 0 | Balance | 10 | 1.00 | 1.45 |
| 2 | 4.5 | 0 | 0 | 0 | 7 | 1 | 0 | 8.8 | Balance | 8 | 0.90 | 1.62 |
| 3 | 4 | 4 | 0 | 0 | 0 | 3 | 2 | 0 | Balance | 8 | 1.00 | 1.42 |
| 4 | 5 | 0 | 0 | 0 | 0 | 0 | 0 | 0 | Balance | 5 | 1.00 | 1.72 |
| 5 | 6 | 0 | 2 | 2 | 0 | 0 | 0 | Balance | 0 | 10 | 0.00 | 1.02 |
| 6 | 4.5 | 0 | 0 | 0 | 7 | 0 | 1 | Balance | 8.8 | 8 | 0.10 | 1.23 |
| 7 | 4 | 4 | 0 | 0 | 0 | 3 | 2 | Balance | 0 | 8 | 0.00 | 1.00 |
| 8 | 5 | 0 | 0 | 0 | 0 | 0 | 0 | Balance | 0 | 5 | 0.00 | 1.35 |
| 9 | 4.5 | 0 | 0 | 0 | 7 | 0 | 1 | 17.5 | Balance | 8 | 0.8 | 1.75 |
| 10 | 4.5 | 0 | 0 | 0 | 7 | 1 | 0 | Balance | 17.5 | 8 | 0.20 | 1.37 |

Note 1) Powder according to claims 2 and 4: 1 to 8
Note 2) Powder according to claim 3: 2, 3, 6, 7, 9 and 10

Powders 1 to 10 thus obtained were then mixed by the combination as shown in Table 3 to reach a target material composition shown in Table 3. Each mixed powder thus obtained was placed into an encapsulating can made of SC material and having an inner dimension of a diameter of 200 mm and a length of 100 mm, followed by a degassing vacuum encapsulation at an ultimate vacuum of 0.1 Pa or less. Thereafter, in the case of HIP (Hot Isostatic Pressing), the mixed powder was consolidated to form a consolidated body at a heating temperature of 1000 to 1300° C. and a pressure of 80 to 150 MPa for a holding time of 5 hours. In the case of an upset method, the mixed powder was consolidated to form a consolidation body at a heating temperature of 750 to 1000° C. and a pressure of 450 to 1000 MPa. The consolidated body was machined by wire cutting, lathe processing and surface grinding to produce a specimen having a final dimension with a diameter of 180 mm and a thickness of 7 mm. The following evaluations were conducted on the specimen thus obtained. The results are shown in table 3.

### Evaluation 2: PTF Value

The PTF value of the target material was measured according to ASTM F1761-00. For comparison, the target material was produced by consolidating a single powder with the same composition as the target material on the same condition for measuring the PTF value.

The difference of these PTF values, that is, [PTF (unit: %) of the target material by the mixed powder]−[PTF (unit: %) of the target material by the single powder], was measured.

### Evaluation 3: Relative Density

The density of the target material was measured by a volume weight method (a dimension and a weight of the machined target material were measured to calculate the density according to weight/volume). The relative density was obtained as a ratio of an actually measured density to the calculated density, followed by evaluation according to the following criteria.

A: 99% or more

B: 98% or more and less than 99%

C: less than 98%

### Evaluation 4: Corrosion Resistance

The target material was subjected to a salt spray test in accordance with ES Z 2371. At this time, the target material after exposure to spraying of a NaCl solution of 5% by weight for 24 hours was observed to visually confirm presence/absence of rust on the target material for evaluation according to the following criteria.

A: No rust generated

B: Generation of rust on part of the target material

C: Generation of rust over the entire surface of the target material

TABLE 3

| | | | | | | | | | | (Zr + | | | | Consol- | Consol- | | | |
|---|---|---|---|---|---|---|---|---|---|---|---|---|---|---|---|---|---|---|
| | | | | | | | | | | Hf + | | | | idation | idation | Differ- | Rela- | Corro- |
| | | | | | | | | | | Nb + | Fe/ | Raw- | | Temper- | Pres- | ence | tive | sion |
| | Constituent of Quenched Thin Strip (at %) | | | | | | | | | Ta) + | (Fe + | Material | Meth- | ature | sure | of PTF | Den- | Resis- |
| No. | Fe | Zr | Hf | Nb | Ta | B | Al | Cr | Co | B/2 | Co) | Powder | od | (° C.) | (MPa) | (%) | sity | tance |

Examples of Present Inv.

| | | | | | | | | | | | | | | | | | | |
|---|---|---|---|---|---|---|---|---|---|---|---|---|---|---|---|---|---|---|
| A | 36.0 | 6 | 0 | 2 | 2 | 0 | 0 | 0 | Bal. | 10 | 0.40 | 1 + 5 | H | 1000 | 150 | 8 | A | B |
| B | 44.3 | 4.5 | 0 | 0 | 0 | 7 | 0.5 | 0.5 | Bal. | 8 | 0.50 | 2 + 6 | H | 1000 | 150 | 11 | A | A |
| C | 34.8 | 4 | 4 | 0 | 0 | 0 | 3 | 3 | Bal. | 8 | 0.40 | 3 + 7 | H | 1250 | 100 | 7 | A | A |
| D | 19.0 | 5 | 0 | 0 | 0 | 0 | 0 | 0 | Bal. | 5 | 0.20 | 4 + 8 | U | 800 | 550 | 5 | A | B |
| E | 57.5 | 4.5 | 0 | 0 | 0 | 7 | 0.7 | 0.3 | Bal. | 8 | 0.65 | 2 + 6 | U | 1000 | 850 | 15 | A | A |
| F | 45.5 | 4.5 | 2 | 0 | 0 | 0 | 1.5 | 1 | Bal. | 6.5 | 0.50 | 3 + 8 | U | 1000 | 450 | 10 | A | A |
| G | 44.3 | 4.5 | 0 | 0 | 0 | 7 | 0 | 1 | Bal. | 8 | 0.50 | 6 + 9 | H | 1000 | 150 | 1 | A | A |
| H | 44.3 | 4.5 | 0 | 0 | 0 | 7 | 1 | 0 | Bal. | 8 | 0.50 | 2 + 10 | H | 1000 | 150 | 2 | A | A |
| I | 36.0 | 6 | 0 | 2 | 2 | 0 | 0 | 0 | Bal. | 10 | 0.40 | 1 + 5 | H | 1000 | 80 | 9 | C | B |
| J | 19.0 | 5 | 0 | 0 | 0 | 0 | 0 | 0 | Bal. | 5 | 0.20 | 4 + 8 | U | 750 | 550 | 6 | C | B |

Note 1) Target materials A to F, I and J are target materials according to claims 2 and 4
Note 2) Target materials B, C, E, F and G are target materials according to claim 3
Note 3) Method: H = HIP, U = Upset
Note 4) PTF value (a difference between a target material derived from a mixed powder and that derived from a single powder)

In addition, a powder of Co (0)-Fe (balance)-2Zr and a powder of Co (balance)-Fe (0)-10Zr were mixed together to a total composition of Co (balance)-47Fe-6Zr, followed by upset-consolidation at 1000° C. and 500 MPa to form a target material (relative density of 99.7%). In a sputtering with this target material (Ar pressure of 0.5 Pa and DC power of 500 W), however, a large number of concave and convex portions were generated on the surface of the target material with the number of the particles being 2.5 times of that of the target material consolidated on the same condition from the single powder. The term “particle” means projections generated on the sputtered thin film to cause defects.

Further, a powder of Co (0)-Fe (balance)-3Zr-2Nb and a powder of Co (balance)-Fe (0)-6Zr-7Nb were mixed together to a total composition of Co (balance)-45.5Fe-4.5Zr-4.5Nb, followed by an upset-consolidation at 1000° C. and 500 MPa to form a target material (relative density of 99.5%). In a sputtering with this target material (Ar pressure of 0.5 Pa and DC power of 500 W), however, a large number of concave and convex portions are generated on the surface of the target material with the number of the particles 2.3 times of that of the target material consolidated on the same condition from the single powder. It is assumed that this is due to a large difference in Zr or Nb amounts between the both powders in any target material (It is known that a sputtering rate of each of Zr, Hf, Nb, Ta and B is lower than that of each of Co and Fe. It is therefore assumed that this difference in sputtering rate caused development of concave and convex portions on the surface to be a cause of particle generation).

### Results

As shown in Table 3, the target materials using Powders 1 to 8 (Target Materials A to F, I and J) have a large difference in PTF, exhibiting an effect of improving PTF significantly, compared with the target materials using the Powders 9 and 10 (Target Materials G and H).

In Table 3, it was found that rust was partly generated by the salt spray test on the target materials (Target Materials A, D, I and J) using a powder (Powders 1 to 4) satisfying Fe/(Fe+Co) of 1.00 to 0.90 (at % ratio) and (Zr+Hf+Nb+Ta)+B/2 of 3 to 12 at % without Al and Cr. On the other hand, it was also found out that rust was not generated by the salt spray test on the target materials (Target Materials B, C and E to H) using a powder (Powders 2, 3 and 9) satisfying Fe/(Fe+Co) of 1.00 to 0.90 (at % ratio) and (Zr+Hf+Nb+Ta)+B/2 of 3 to 12 at % with Al and Cr. In view of the above, an improvement in corrosion resistance was observed in the target material.

Powders based on Powder 3 and Powder 7 with the Cr amounts increased to 3 at % were mixed together to Co (balance)-34.4 Fe-4Zr-4Hf-3Al-3Cr, followed by consolidation at 1250° C. and 100 MPa by HIP to produce a target material. However, since rust was not generated on the target material by the salt spray test in the same way as Target Material C. It is therefore confirmed that, when Al+Cr in the raw-material powder exceeds 5 at %, an effect of improving corrosion resistance of the target material was no longer improved.

When a mixed powder of Target Material A and Target Material C was consolidated by HIP at 1300° C. and at 100 MPa, a large number of molten solidification pores were observed inside the consolidation body.

In regard to the compositions of Target Materials B, C and E, cracks or defects were partly observed in the consolidation body in the case of using a single powder consolidated on the same condition as the raw-material, while no cracks or defects were observed at all in the case of using the mixed powder. In consequence, an effect of preventing cracks or defects at machining by use of two kinds of the raw-material powders was confirmed.

The relative density of each of Target Materials A, B and E was 99% or more, while the relative density of each consolidation body in the case of using a single powder consolidated on the same condition as the raw-material in regard to these compositions was 98.2%, 98.4% and 98.4%. In consequence, it was confirmed that the relative density was high by use of two kinds of the raw-material powders even if the target material was consolidated on the same condition.

What is claimed is:

1. A method for producing a sputtering target material, comprising the steps of:
a) mixing a first powder and a second powder to form a mixed powder,
wherein the first powder comprises:
one or more of Zr, Hf, Nb, Ta and B in an amount satisfying 3 at %≦(Zr+Hf+Nb+Ta)+B/2≦12 at %;
Al and Cr: 0 to 5 at % in total; and
the balance being Co and Fe in an amount of satisfying 1.00≧Fe/(Fe+Co)≧0.90 (at % ratio) with unavoidable impurities, and
wherein the second powder comprises:
one or more of Zr, Hf, Nb, Ta and B having an amount of satisfying 3 at %≦(Zr+Hf+Nb+Ta)+B/2≦12 at %;
Al and Cr: 0 to 5 at % in total; and
the balance being Co and Fe in an amount satisfying 0.00≦Fe/(Fe+Co)≦0.10 (at % ratio) with unavoidable impurities; and
b) consolidating the mixed powder at 800 to 1250° C. and at 100 to 1000 MPa to form the sputtering target material,
wherein the sputtering target material comprises:
one or more of Zr, Hf, Nb, Ta and B in an amount satisfying 5 at %≦(Zr+Hf+Nb+Ta)+B/2≦10 at % and having 7 at % or less of B;
Al and Cr: 0 to 5 at % in total; and
the balance being Co and Fe in an amount satisfying 0.20≦Fe/(Fe+Co)≦0.65 (at % ratio) with unavoidable impurities.

2. The method according to claim 1, wherein only the first powder or both of the first powder and the second powder comprise 5 at % or less of Al+Cr, and wherein the target material comprises 5 at % or less of Al+Cr as a whole.

3. The method according to claim 1, wherein a difference between a PTF value of the target material and a PFT value of a target material produced by the same method as the method according to claim 1 except for using a single powder of the same composition as a final composition of the target material in place of the mixed powder ranges from 5 to 15.

4. The method according to claim 2, wherein a difference between a PTF value of the target material and a PFT value of a target material produced by the same method as the method according to claim 2 except for using a single powder of the same composition as a final composition of the target material in place of the mixed powder ranges from 5 to 15.
